(19) United States
(12) Patent Application Publication
(10) Pub. No.: US 2023/0371254 A1
(43) Pub. Date: Nov. 16, 2023

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Donghoon KWON, Suwon-si (KR); Hyo-Jung Kim, Suwon-si (KR); Chungki Min, Suwon-si (KR); Boun Yoon, Suwon-si (KR)

(73) Assignee: Samsung Electronics Co., Ltd., Suwon-so (KR)

(21) Appl. No.: 18/062,169

(22) Filed: Dec. 6, 2022

(30) Foreign Application Priority Data
May 10, 2022 (KR) 10-2022-0057469

(51) Int. Cl. H10B 43/27; H10B 41/10; H10B 41/27; H10B 43/10

(52) U.S. Cl. CPC H01L 27/11582; H01L 27/11519; H01L 27/11556; H01L 27/11565

(57) ABSTRACT

A semiconductor device may include a gate stack including insulating patterns and conductive patterns, which are alternately stacked, first block channel structures penetrating the gate stack, second block channel structures penetrating the gate stack, and an isolation structure penetrating the gate stack. The isolation structure may include a block isolation structure, a first word line isolation structure, and a second word line isolation structure. The block isolation structure may include a first side surface connected to a side surface of the first word line isolation structure, and a second side surface connected to a side surface of the second word line isolation structure, and the first block channel structures comprise an intervening channel structure between the first and second side surfaces of the block isolation structure.

### CROSS-REFERENCE TO RELATED APPLICATIONS

This U.S. non-provisional patent application claims priority under 35 U.S.C. § 119 to Korean Patent Application No. 10-2022-0057469, filed on May 10, 2022, in the Korean Intellectual Property Office, the entire contents of which are hereby incorporated by reference.

### BACKGROUND

Various example embodiments relate to a semiconductor device and/or an electronic system including the same, and in particular, to a semiconductor device with an isolation structure and/or an electronic system including the same.

Due to their small-sized, multifunctionality, and/or low-cost characteristics, semiconductor devices are being esteemed as important elements in the electronics industry. The semiconductor devices are classified into a semiconductor memory device for storing data, a semiconductor logic device for processing data, and a hybrid semiconductor device including both of memory and logic elements.

With a trend of high speed and low power consumption of electronic devices, semiconductor devices in the electronic devices are also required or desired or expected to have high operating speeds and/or low operating voltages, and in order to satisfy or at least partially satisfy this desire, it is necessary or expected to increase an integration density of the semiconductor device. However, as the integration density of the semiconductor device increases, the semiconductor device may suffer from deterioration in electric characteristics and/or production yield. Accordingly, many studies are being conducted to improve the electric characteristics and production yield of the semiconductor device.

### SUMMARY

Various example embodiments provide a semiconductor device with improved electrical and/or reliability characteristics, and/or an electronic system including the same.

According to various example embodiments, a semiconductor device may include a gate stack including insulating patterns and conductive patterns, which are alternately stacked, first block channel structures penetrating the gate stack, second block channel structures penetrating the gate stack, and an isolation structure penetrating the gate stack. The isolation structure may include a block isolation structure between the first block channel structures and the second block channel structures, a first word line isolation structure between the first block channel structures, and a second word line isolation structure between the first block channel structures and adjacent to the first word line isolation structure. The block isolation structure may include a first side surface connected to a side surface of the first word line isolation structure, and a second side surface connected to a side surface of the second word line isolation structure. The first block channel structures may include an intervening channel structure between the first and second side surfaces of the block isolation structure.

Additionally or alternatively, according to various example embodiments, a semiconductor device may include a gate stack including insulating patterns and conductive patterns, which are alternately stacked, bit lines on the gate stack, first block channel structures penetrating the gate stack, second block channel structures penetrating the gate stack, and an isolation structure penetrating the gate stack. The isolation structure may include a block isolation structure between the first block channel structures and the second block channel structures, a first word line isolation structure between the first block channel structures, and a second word line isolation structure between the first block channel structures and adjacent to the first word line isolation structure. The block isolation structure may include a first side surface connected to a side surface of the first word line isolation structure, and a second side surface connected to a side surface of the second word line isolation structure. The bit lines may include a first overlap bit line at least partially overlapping the first and second side surfaces of the block isolation structure, and the first block channel structures may include a first intervening channel structure at least partially overlapped by the first overlap bit line.

According to various example embodiments, an electronic system may include a main substrate, a semiconductor device on the main substrate, and a controller on the main substrate and electrically connected to the semiconductor device. The semiconductor device may include a gate stack including insulating patterns and conductive patterns, which are alternately stacked, bit lines on the gate stack, first block channel structures penetrating the gate stack, second block channel structures penetrating the gate stack, and an isolation structure penetrating the gate stack. The isolation structure may include a block isolation structure between the first block channel structures and the second block channel structures, a first word line isolation structure between the first block channel structures, and a second word line isolation structure between the first block channel structures and adjacent to the first word line isolation structure. The bit lines may include a first overlap bit line, which is at least partially overlapping the block isolation structure, a second overlap bit line, which is at least partially overlapping the block isolation structure, and a share bit line between the first overlap bit line and the second overlap bit line. The first block channel structures may include a first intervening channel structure, which is electrically connected to the first overlap bit line, and a first sharing channel structure connected to the share bit line. The second block channel structures may include a second intervening channel structure electrically connected to the second overlap bit line, and a second sharing channel structure electrically connected to the share bit line.

### BRIEF DESCRIPTION OF THE DRAWINGS

FIG. 1A is a diagram schematically illustrating an electronic system including a semiconductor device, according to various example embodiments.

FIG. 1B is a perspective view schematically illustrating an electronic system including a semiconductor device, according to various example embodiments.

FIGS. 1C and 1D are sectional views schematically illustrating semiconductor packages according to various example embodiments.

FIG. 2A is a plan view illustrating a semiconductor device according to various example embodiments.

FIG. 2B is a sectional view taken along a line A-A′ of FIG. 2A.

FIG. 2C is a sectional view taken along a line B-B′ of FIG. 2A.

FIG. 2D is an enlarged view illustrating a portion ‘C’ of FIG. 2A.

FIG. 2E is a diagram illustrating bit lines in the semiconductor device according to FIGS. 2A to 2D.

FIG. 3 is a plan view illustrating a semiconductor device according to various example embodiments.

FIG. 4 is a plan view illustrating a semiconductor device according to various example embodiments.

FIG. 5 is a plan view illustrating a semiconductor device according to various example embodiments.

FIG. 6 is a plan view illustrating a semiconductor device according to various example embodiments.

### DETAILED DESCRIPTION

Various example embodiments of inventive concepts will now be described more fully with reference to the accompanying drawings, in which example embodiments are shown.

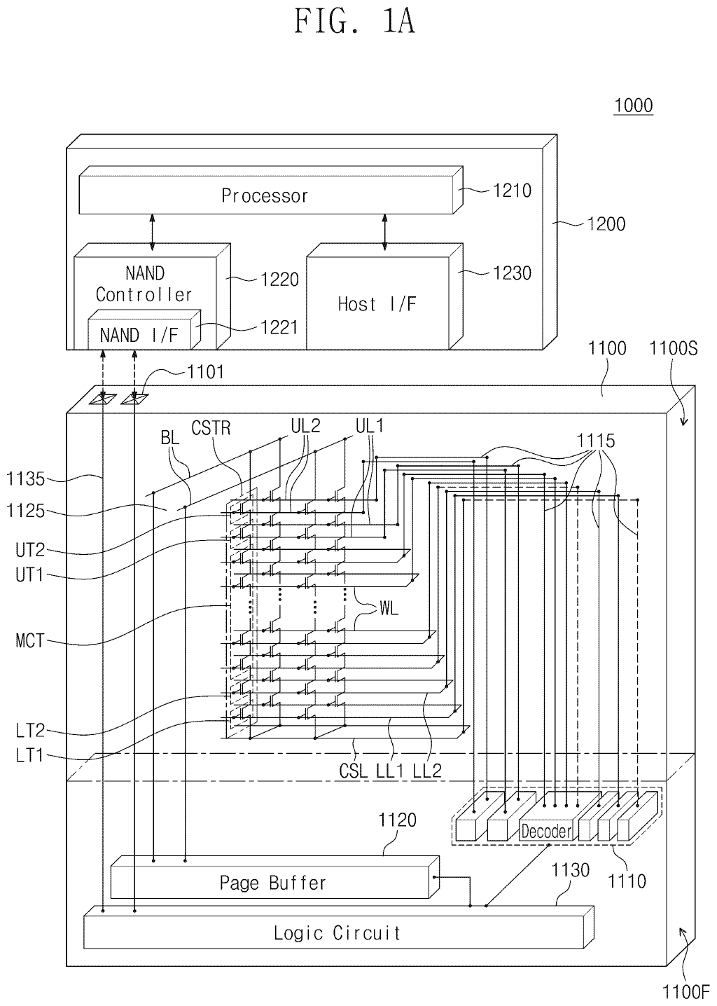

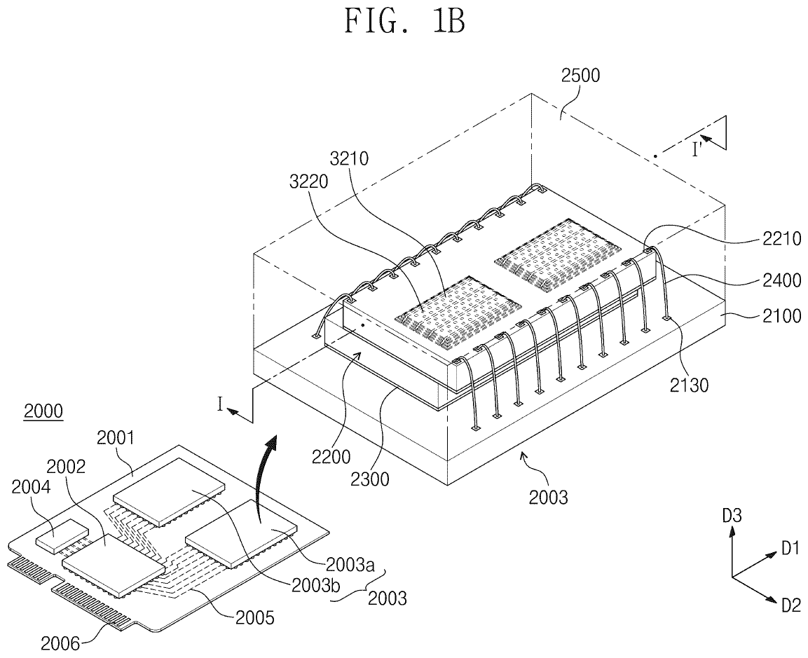

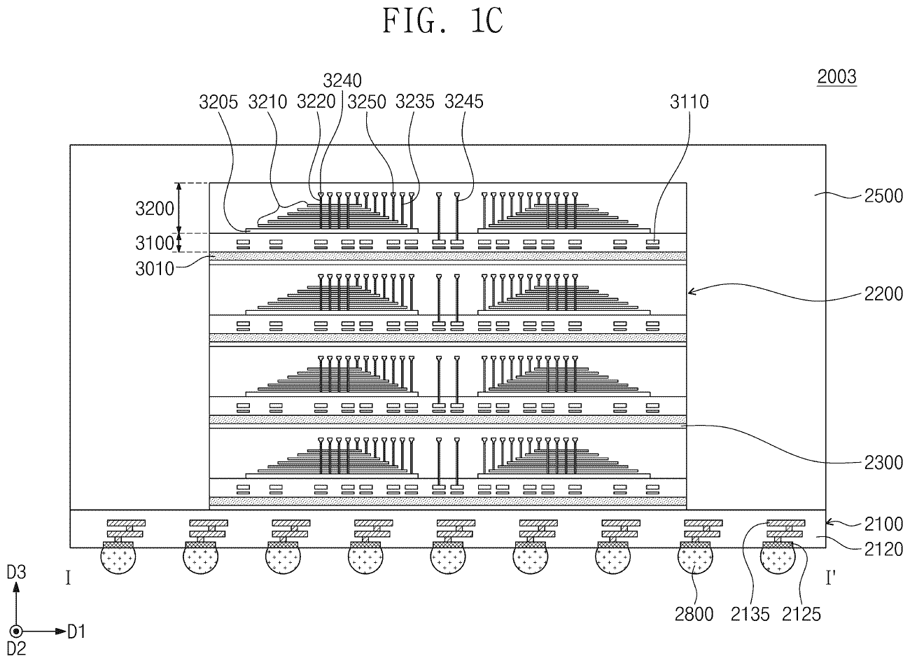

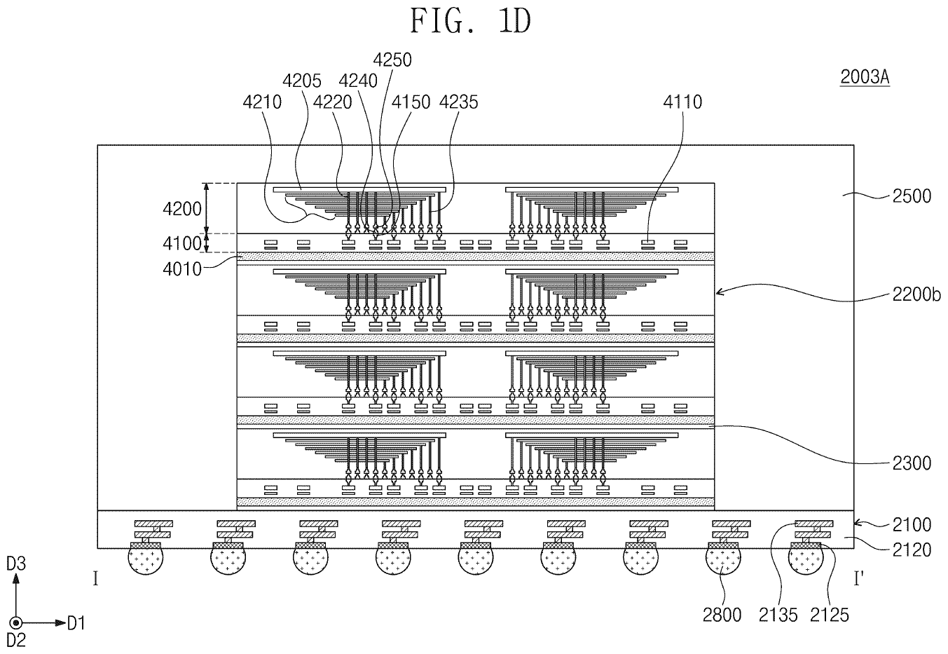

FIG. 1A is a diagram schematically illustrating an electronic system including a semiconductor device, according to various example embodiments.

Referring to FIG. 1A, an electronic system 1000 according to various example embodiments may include a semiconductor device 1100 and a controller 1200, which is electrically connected to the semiconductor device 1100. The electronic system 1000 may be a storage device including one or more semiconductor devices 1100 or an electronic device including the storage device. For example, the electronic system 1000 may be or may include one or more of a solid-state drive (SSD) device, a universal serial bus (USB), a computing system, a medical system, or a communication system, in which at least one semiconductor device 1100 is provided.

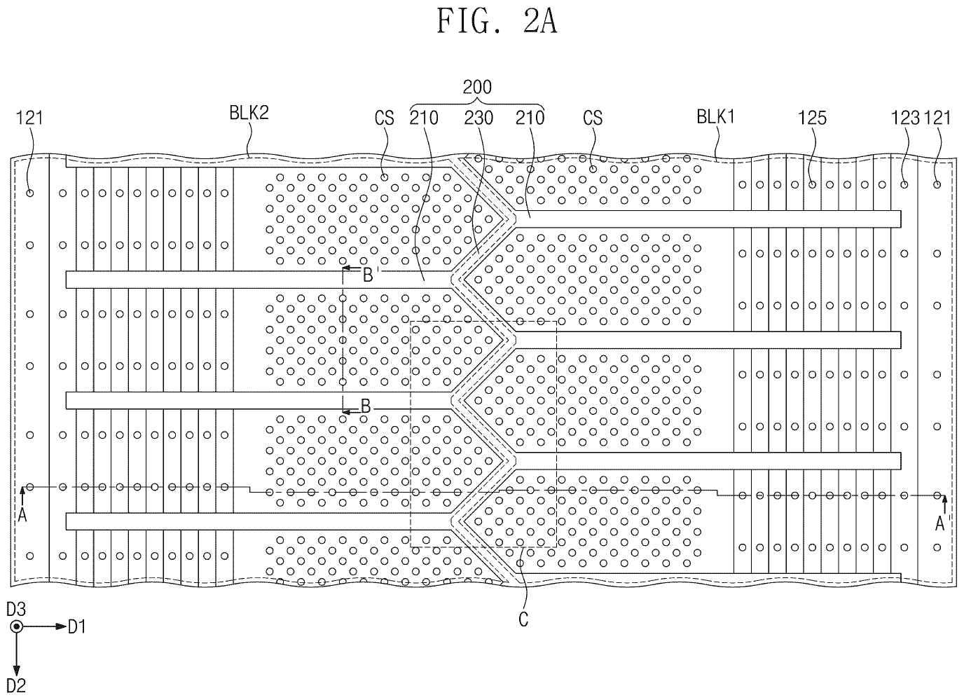

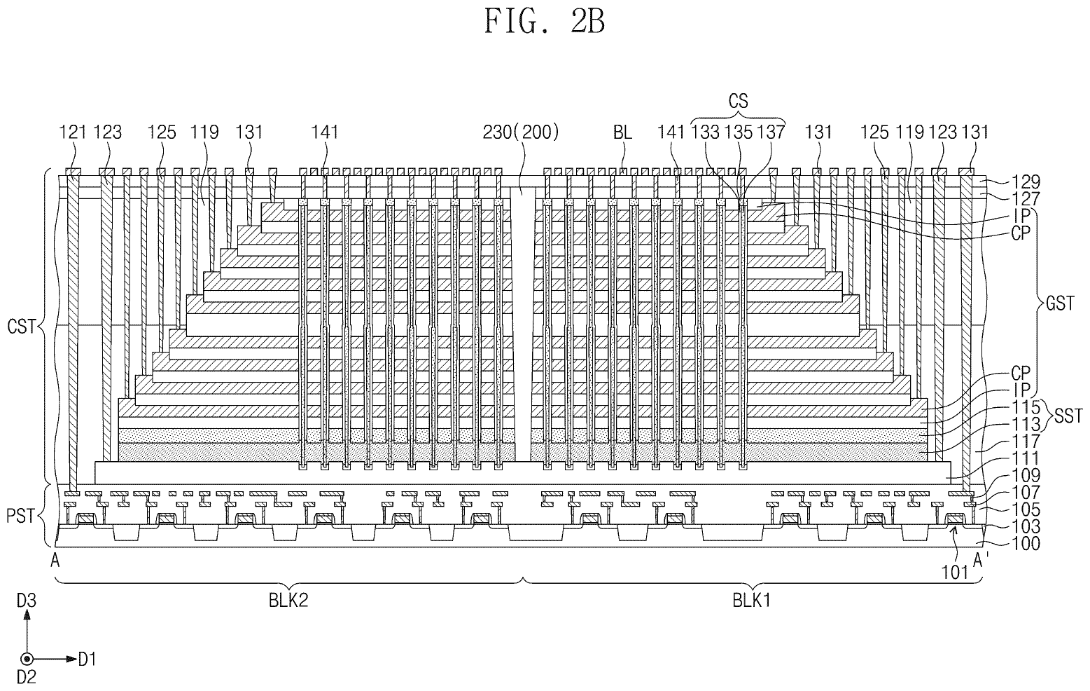

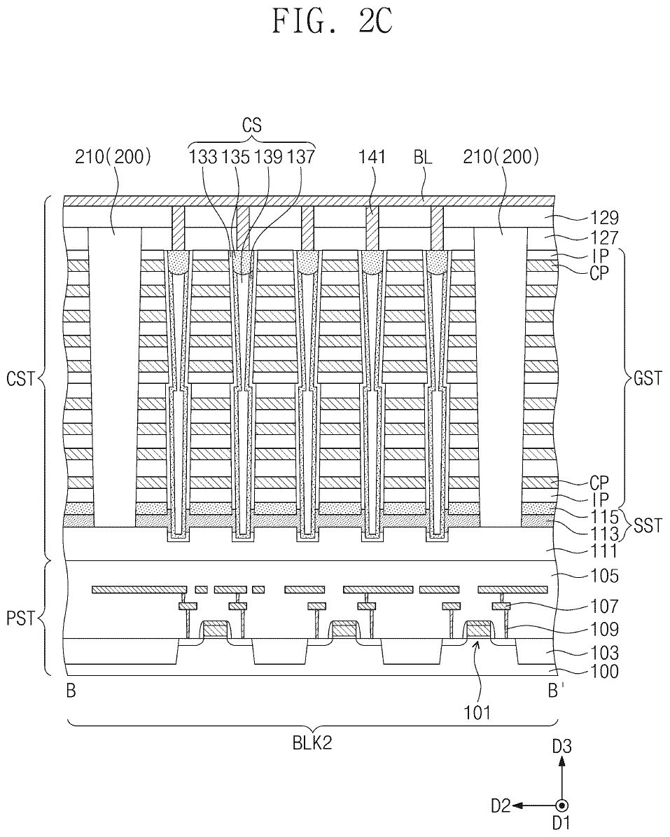

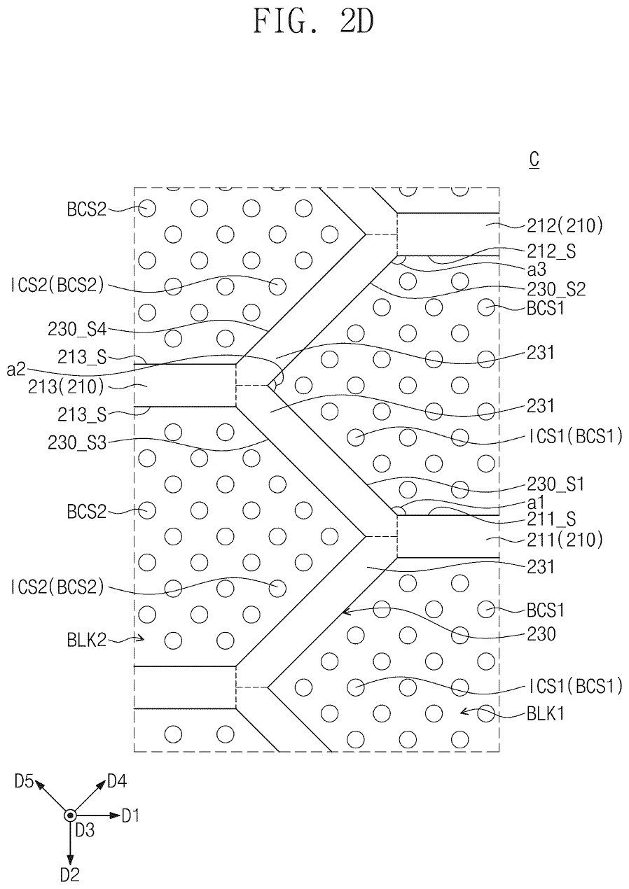

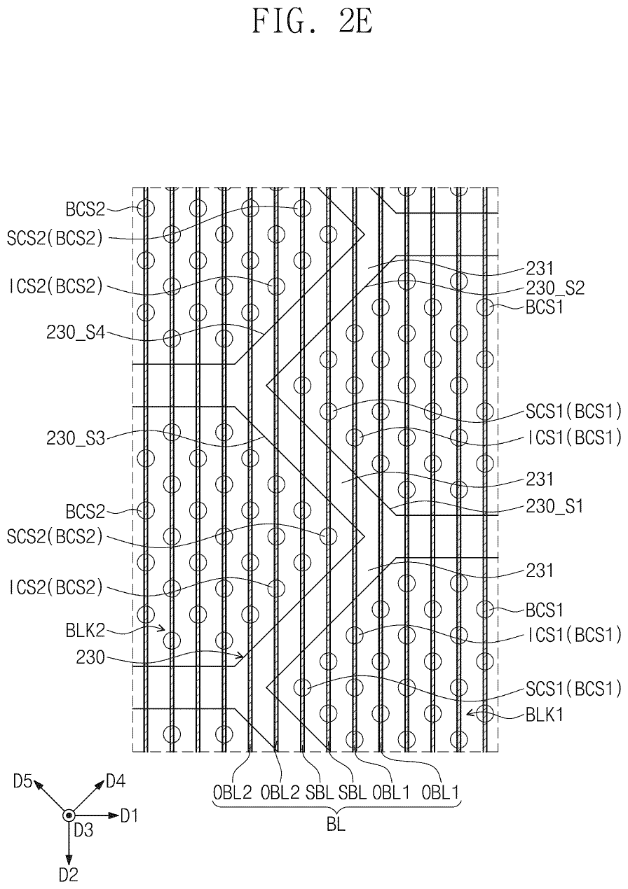

The semiconductor device 1100 may be or may include a nonvolatile memory device and may be or may include, for example, a NAND FLASH memory device, which will be described with reference to FIGS. 2A, 2B, 2C, and 2D. The semiconductor device 1100 may include a first structure 1100F and a second structure 1100S on the first structure 1100F. In some example embodiments, the first structure 1100F may be disposed beside the second structure 1100S. The first structure 1100F may be or may include a peripheral circuit structure, which includes a decoder circuit 1110, a page buffer 1120, and a logic circuit 1130. The second structure 1100S may be or may include a memory cell structure, which includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2, which are adjacent to the common source line CSL, upper transistors UT1 and UT2, which are adjacent to the bit line BL, and a plurality of memory cell transistors MCT, which are disposed between the lower transistors LT1 and LT2 and the upper transistors UT1 and UT2. The number of the lower transistors LT1 and LT2 and/or the number of the upper transistors UT1 and UT2 may be variously changed, according to some example embodiments.

In various example embodiments, the upper transistors UT1 and UT2 may include a string selection transistor, and the lower transistors LT1 and LT2 may include a ground selection transistor. The gate lower lines LL1 and LL2 may be respectively used as gate electrodes of the lower transistors LT1 and LT2. The word lines WL may be used as gate electrodes of the memory cell transistors MCT, respectively, and the gate upper lines UL1 and UL2 may be used as gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115, which extend from the first structure 1100F into the second structure 1100S. The bit lines BL may be electrically connected to the page buffer 1120 through second connection lines 1125, which extend from the first structure 1100F into the second structure 1100S.

In the first structure 1100F, the decoder circuit 1110 and the page buffer 1120 may be configured to perform a control operation on at least a selected one of the memory cell transistors MCT. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is extended from the first structure 1100F to the second structure 1100S.

The controller 1200 may include a processor 1210, a NAND controller 1220, and a host interface 1230. In some example embodiments, the electronic system 1000 may include a plurality of semiconductor devices 1100, and in this case, the controller 1200 may be configured to control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221 which is used for communication with the semiconductor device 1100. The NAND interface 1221 may be used to transmit and/or receive control commands to control the semiconductor device 1100, data to be written in and/or read from the memory cell transistors MCT of the semiconductor device 1100, and so forth. The host interface 1230 may be configured to allow for communication between the electronic system 1000 and an external host. When a control command is received from the external host through the host interface 1230, the processor 1210 may control the semiconductor device 1100 in response to the control command.

FIG. 1B is a perspective view schematically illustrating an electronic system including a semiconductor device, according to some example embodiments.

Referring to FIG. 1B, an electronic system 2000 according to various example embodiments may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 and to each other by interconnection patterns 2005, which are formed in the main substrate 2001.

The main substrate 2001 may include a connector 2006, which includes a plurality of pins coupled to an external host (not shown). In the connector 2006, the number and/or the arrangement of the pins may depend on a communication interface between the electronic system 2000 and the external host. In some example embodiments, the electronic system 2000 may communicate with the external host, in accordance with one of interfaces, such as one or more of a universal serial bus (USB), peripheral component interconnect express (PCI-Express), serial advanced technology attachment (SATA), universal flash storage (UFS) M-PHY, or the like. In some example embodiments, the electronic system 2000 may be driven by an electric power, which is supplied from the external host through the connector 2006. The electronic system 2000 may further include a power management integrated circuit (PMIC) (not shown) that is configured to distribute a power, which is supplied from the external host to the controller 2002 and the semiconductor package 2003.

The controller 2002 may be configured to control a writing or reading operation on the semiconductor package 2003 and to improve an operation speed of the electronic system 2000.

The DRAM 2004 may be or may include a buffer memory that is configured to relieve or at least partially relieve technical difficulties caused by a difference in speed between the semiconductor package 2003, which serves as a data storage device, and an external host. In some example embodiments, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller (not shown) for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200, which are provided on the package substrate 2100, adhesive layers 2300, which are respectively disposed in bottom surfaces of the semiconductor chips 2200, a connection structure 2400, which electrically connects the semiconductor chips 2200 to the package substrate 2100, and a molding layer 2500, which is provided on the package substrate 2100 to cover the semiconductor chips 2200 and the connection structure 2400.

The package substrate 2100 may be or may include a printed circuit board, which includes package upper pads 2130. Each of the semiconductor chips 2200 may include an input/output pad 2210. The input/output pad 2210 may correspond to the input/output pad 1101 of FIG. 1A. Each of the semiconductor chips 2200 may include gate stacks 3210 and memory channel structures 3220. Each of the semiconductor chips 2200 may include a semiconductor device to be described with reference to FIGS. 2A, 2B, 2C, and 2D.

In some example embodiments, the connection structure 2400 may be or may include a bonding wire electrically connecting the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. Alternatively or additionally, in each of the first and second semiconductor packages 2003a and 2003b, the semiconductor chips 2200 may be electrically connected to each other by a connection structure including through-silicon vias (TSVs), not by or in addition to the connection structure 2400 provided in the form of bonding wires.

In some example embodiments, the controller 2002 and the semiconductor chips 2200 may be included in a single package. In some example embodiments, the controller 2002 and the semiconductor chips 2200 may be mounted on an additional interposer substrate different from the main substrate 2001 and may be connected to each other through interconnection lines, which are provided in the interposer substrate.

FIGS. 1C and 1D are sectional views schematically illustrating semiconductor packages according to some example embodiments. Each of FIGS. 1C and 1D schematically illustrates an example of the semiconductor package 2003 of FIG. 1B taken along a line I-I′ of FIG. 1B.

Referring to FIG. 1C, in the semiconductor package 2003, the package substrate 2100 may be a printed circuit board. The package substrate 2100 may include a package substrate body portion 2120, upper pads 2130 disposed on a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000, which is shown in FIG. 1B, through conductive connecting portions 2800.

Each of the semiconductor chips 2200 may include a semiconductor substrate 3010 along with a first structure 3100 and a second structure 3200, which are sequentially stacked on the semiconductor substrate 3010. The first structure 3100 may include a peripheral circuit region provided with peripheral lines 3110. The second structure 3200 may include a common source line 3205, a gate stack 3210 on the common source line 3205, the memory channel structures 3220, which are provided to penetrate the gate stack 3210, bit lines 3240, which are electrically connected to the memory channel structures 3220, and gate connection lines, which are electrically connected to the word lines WL (e.g., see FIG. 1A) of the gate stack 3210.

Each of the semiconductor chips 2200 may be electrically connected to the peripheral lines 3110 of the first structure 3100 and may include a penetration line 3245, which is extended into the second structure 3200. The penetration line 3245 may be provided to penetrate the gate stack 3210, and in some example embodiments, the penetration line 3245 may be further disposed outside the gate stack 3210.

Referring to FIG. 1D, in a semiconductor package 2003A, each of semiconductor chips 2200a may include a semiconductor substrate 4010, a first structure 4100 on the semiconductor substrate 4010, and a second structure 4200, which is disposed on the first structure 4100 and is bonded to the first structure 4100 by a wafer bonding method.

The first structure 4100 may include a peripheral circuit region, in which a peripheral line 4110 and first junction structures 4150 are provided. The second structure 4200 may include a common source line 4205, a gate stack 4210, which is provided between the common source line 4205 and the first structure 4100, memory channel structures 4220, which are provided to penetrate the gate stack 4210, and second junction structures 4250, which are respectively and electrically connected to the memory channel structures 4220 and the word lines WL (e.g., see FIG. 1A) of the gate stack 4210. For example, the second junction structures 4250 may be electrically connected to the memory channel structures 4220 and the word lines WL (e.g., see FIG. 1A), respectively, through bit lines 4240, which are electrically connected to the memory channel structures 4220, and through gate connection lines, which are electrically connected to the word lines WL (e.g., see FIG. 1A). The first junction structures 4150 of the first structure 4100 and the second junction structures 4250 of the second structure 4200 may be bonded to and in contact with each other. In some example embodiments, the bonding portion of the first and second junction structures 4150 and 4250 may be formed of copper (Cu); however, example embodiments are not limited thereto.

The semiconductor chips 2200 of FIG. 1C or the semiconductor chips 2200a of FIG. 1D may be electrically connected to each other by the connection structures 2400, which are provided in the form of bonding wires. Alternatively or additionally, in some example embodiments, semiconductor chips, which are provided in the same semiconductor package as the semiconductor chips 2200 of FIG. 1C or the semiconductor chips 2200a of FIG. 1D, may be electrically connected to each other through a connection structure including the through-silicon vias (TSVs).

FIG. 2A is a plan view illustrating a semiconductor device according to some example embodiments. FIG. 2B is a sectional view taken along a line A-A′ of FIG. 2A. FIG. 2C is a sectional view taken along a line B-B′ of FIG. 2A. FIG. 2D is an enlarged view illustrating a portion ‘C’ of FIG. 2A. FIG. 2E is a diagram illustrating bit lines in the semiconductor device according to FIGS. 2A to 2D.

Referring to FIGS. 2A, 2B, and 2C, a semiconductor device according to some example embodiments may include a peripheral circuit structure PST and a memory cell structure CST on the peripheral circuit structure PST.

The peripheral circuit structure PST may include a substrate 100. The substrate 100 may be a plate-shaped structure that is extended parallel to a plane defined by a first direction D1 and a second direction D2. The first and second directions D1 and D2 may not be parallel to each other. As an example, the first and second directions D1 and D2 may be horizontal directions (e.g., horizontal with respect to an upper surface of the substrate 100) that are orthogonal to each other. In some example embodiments, the substrate 100 may be a semiconductor substrate. As an example, the substrate 100 may be formed of or include at least one of silicon, germanium, silicon-germanium, GaP, or GaAs. In some example embodiments, the substrate 100 may be a silicon-on-insulator (SOI) substrate or a germanium-on-insulator (GOI) substrate.

The peripheral circuit structure PST may include a peripheral circuit insulating layer 105 on the substrate 100. The peripheral circuit insulating layer 105 may be formed of or include at least one of insulating materials. As an example, the peripheral circuit insulating layer 105 may be formed of or include oxide. In some example embodiments, the peripheral circuit insulating layer 105 may be or may include a multi-layered structure including a plurality of insulating layers.

The peripheral circuit structure PST may further include a peripheral transistor 101. The peripheral transistor 101 may be provided between the substrate 100 and the peripheral circuit insulating layer 105. In some example embodiments, the peripheral transistor 101 may include source/drain regions, a gate electrode, and a gate insulating layer. The peripheral transistor 101 may be a planar transistor; however, example embodiments are not limited thereto, and the peripheral transistor 101 may be a three-dimensional transistor. Device isolation layers 103 may be provided in the substrate 100. The peripheral transistor 101 may be disposed between the device isolation layers 103. The device isolation layer 103 may be formed of or include at least one of insulating materials.

The peripheral circuit structure PST may further include peripheral contacts 109 and peripheral lines 107. The peripheral contact 109 may be connected to the peripheral transistor 101 or the peripheral line 107, and the peripheral line 107 may be connected to the peripheral contact 109. The peripheral contact 109 and the peripheral line 107 may be provided in the peripheral circuit insulating layer 105. The peripheral contact 109 and the peripheral line 107 may be formed of or include at least one of conductive materials.

The memory cell structure CST may include a semiconductor layer 111, a source structure SST, a gate stack GST, memory channel structures CS, a first cover insulating layer 117, a second cover insulating layer 119, a third cover insulating layer 127, a fourth cover insulating layer 129, an isolation structure 200, first contacts 121, second contacts 123, third contacts 125, bit line contacts 141, bit lines BL, and conductive lines 131.

The semiconductor layer 111 may be provided on the peripheral circuit insulating layer 105 of the peripheral circuit structure PST. The source structure SST may be provided on the semiconductor layer 111. The source structure SST may include a first source layer 113, which is provided on the semiconductor layer 111, and a second source layer 115, which is provided on the first source layer 113. In some example embodiments, the semiconductor layer 111, the first source layer 113, and the second source layer 115 may be formed of or include at least one of semiconductor materials. As an example, the semiconductor layer 111, the first source layer 113, and the second source layer 115 may be formed of or include polysilicon such as doped or undoped polysilicon.

The gate stack GST may be provided on the second source layer 115. The gate stack GST may include insulating patterns IP and conductive patterns CP, which are alternately stacked in a third direction D3. The third direction D3 may not be parallel to the first and second directions D1 and D2. As an example, the third direction D3 may be a vertical direction that is orthogonal to the first and second directions D1 and D2.

The insulating patterns IP may be formed of or include at least one of insulating materials. As an example, the insulating patterns IP may be formed of or include oxide. The conductive patterns CP may be formed of or include at least one of conductive materials. As an example, the conductive patterns CP may be formed of or include tungsten.

The memory channel structures CS may be extended in the third direction D3 to penetrate the insulating and conductive patterns IP and CP of the gate stack GST, the second source layer 115, and the first source layer 113. The memory channel structures CS may be surrounded by the insulating and conductive patterns IP and CP of the gate stack GST. The lowermost portion of the memory channel structure CS may be disposed in the semiconductor layer 111.

Each of the memory channel structures CS may include an insulating capping layer 139, a channel layer 137 enclosing the insulating capping layer 139, and a memory layer 133 enclosing the channel layer 137. The insulating capping layer 139, the channel layer 137, and the memory layer 133 may extend in the third direction D3 to penetrate the insulating and conductive patterns IP and CP of the gate stack GST.

The insulating capping layer 139 may be formed of or include at least one of insulating materials. As an example, the insulating capping layer 139 may be formed of or include oxide such as but not limited to silicon oxide. The channel layer 137 may be formed of or include at least one of conductive materials. As an example, the channel layer 137 may be formed of or include polysilicon such as doped or undoped polysilicon. The channel layer 137 may be electrically connected to the first source layer 113. The first source layer 113 may be provided to penetrate the memory layer 133 and may be connected to the channel layer 137.

The memory layer 133 may be configured to store data. In some example embodiments, the memory layer 133 may include a tunnel insulating layer enclosing the channel layer 137, a data storing layer enclosing the tunnel insulating layer, and a blocking layer enclosing the data storing layer.

Each of the memory channel structures CS may further include a bit line pad 135, which is provided on the channel layer 137. The bit line pad 135 may be formed of or include a conductive material. As an example, the bit line pad 135 may be formed of or include at least one of polysilicon or metallic materials.

The first cover insulating layer 117 may cover the peripheral circuit structure PST, the semiconductor layer 111, the source structure SST, and a lower portion of the gate stack GST. The second cover insulating layer 119 may cover the first cover insulating layer 117 and an upper portion of the gate stack GST. The third cover insulating layer 127 may be provided to cover the second cover insulating layer 119, the memory channel structures CS, and the gate stack GST. The fourth cover insulating layer 129 may be provided to cover the third cover insulating layer 127 and the isolation structure 200. The first to fourth cover insulating layers 117, 119, 127, and 129 may be formed of or include at least one of insulating materials.

The first contact 121 may be connected to the peripheral line 107 of the peripheral circuit structure PST. The second contact 123 may be connected to the semiconductor layer 111. The third contact 125 may be connected to the conductive pattern CP of the gate stack GST. The bit line contact 141 may be connected to the bit line pad 135 of the memory channel structure CS. The first to fourth contacts 121, 123, 125, and 141 may be formed of or include a conductive material.

The conductive lines 131 and the bit lines BL may be provided on the fourth cover insulating layer 129. The bit lines BL may be extended in the second direction D2. The conductive line 131 may be connected to one or more of the first contact 121, the second contact 123, or the third contact 125. The bit line BL may be connected to the bit line contact 141. The conductive lines 131 and the bit lines BL may be formed of or include a conductive material.

The memory cell structure CST may include a first memory block BLK1 and a second memory block BLK2. Each of the first and second memory blocks BLK1 and BLK2 may include a memory cell array.

The isolation structure 200 may be extended in the third direction D3 to penetrate the conductive and insulating patterns CP and IP of the gate stack GST. The isolation structure 200 may include word line isolation structures 210 and a block isolation structure 230. The word line isolation structures 210 and the block isolation structure 230 may be formed of or include at least one of insulating materials. As an example, the word line isolation structures 210 and the block isolation structure 230 may be formed of or include oxide such as silicon oxide; however, example embodiments are not limited thereto. In some example embodiments, the word line isolation structures 210 and the block isolation structure 230 may be continuously connected to each other without an interface therebetween to form a single object.

The word line isolation structures 210 may extend in the third direction D3 to penetrate the conductive and insulating patterns CP and IP of the gate stack GST. The word line isolation structures 210 may extend in the first direction D1. The block isolation structure 230 may extend in the third direction D3 to penetrate the conductive and insulating patterns CP and IP of the gate stack GST. The block isolation structure 230 may separate the first memory block BLK1 from the second memory block BLK2.

The word line isolation structures 210 may include the word line isolation structures 210, which are included in the first memory block BLK1, and the word line isolation structures 210, which are included in the second memory block BLK2. The word line isolation structures 210 which are included in the first memory block BLK1 may be disposed at a side of the block isolation structure 230, and the word line isolation structures 210 which are included in the second memory block BLK2 may be disposed at an opposite side of the block isolation structure 230.

In some example embodiments, the word line isolation structure 210 and the block isolation structure 230 may be provided to penetrate the source structure SST and may be connected to the semiconductor layer 111. In some example embodiments, a source contact may be provided in the word line isolation structure 210, and the source contact may be electrically connected to the source structure SST.

Referring to FIG. 2D, the memory channel structures CS may include first block channel structures BCS1, which are included in the first memory block BLK1, and second block channel structures BCS2, which are included in the second memory block BLK2.

The block isolation structure 230 may be disposed between the first block channel structures BCS1 and the second block channel structures BCS2. For example, the first block channel structures BCS1 may be disposed at a side of the block isolation structure 230, and the second block channel structures BCS2 may be disposed at an opposite side of the block isolation structure 230.

The word line isolation structures 210 may include a first word line isolation structure 211, which is disposed between the first block channel structures BCS1, a second word line isolation structure 212, which is disposed between the first block channel structures BCS1, and a third word line isolation structure 213, which is disposed between the second block channel structures BCS2. The first and second word line isolation structures 211 and 212 may be included in the first memory block BLK1, and the third word line isolation structure 213 may be included in the second memory block BLK2. The second word line isolation structure 212 may be the word line isolation structure 210 of the first memory block BLK1 adjacent to the first word line isolation structure 211. The third word line isolation structure 213 may be or may correspond to the word line isolation structure 210 of the second memory block BLK2 adjacent to the first word line isolation structure 211.

The first block channel structures BCS1 may be disposed at both sides of the first word line isolation structure 211, the first block channel structures BCS1 may be disposed at both sides of the second word line isolation structure 212, and the second block channel structures BCS2 may be disposed at both sides of the third word line isolation structure 213.

The block isolation structure 230 may include a plurality of isolation portions 231. Each of the isolation portions 231 of the block isolation structure 230 may connect two word line isolation structures 210 to each other. As an example, the isolation portion 231 of the block isolation structure 230 may be connected to the first word line isolation structure 211 and the third word line isolation structure 213. As an example, the isolation portion 231 of the block isolation structure 230 may be connected to the second word line isolation structure 212 and the third word line isolation structure 213. Two isolation portions 231 of the block isolation structure 230 may be connected to each other. Two isolation portions 231 may be connected to one word line isolation structure 210.

Each of the isolation portions 231 of the block isolation structure 230 may extend in a fourth or fifth direction, e.g. one of D4 or D5. The fourth direction D4 may not be parallel to the first direction D1, the second direction D2, and the third direction D3. As an example, the fourth direction D4 may be a horizontal direction that is orthogonal to the third direction D3. The fifth direction D5 may not be parallel to the first direction D1, the second direction D2, the third direction D3, and the fourth direction D4. As an example, the fifth direction D5 may be a horizontal direction that is orthogonal to the third direction D3. An angle formed between the first direction D1 and the fourth direction D4 may be 45 degrees; however, example embodiments are not limited thereto, and the angle formed between the first direction D1 and the fourth direction D4 may be, for example, any degree between 0 degrees and 90 degrees. An angle formed between the first direction D1 and the fifth direction D5 may be 135 degrees; however, example embodiments are not limited thereto, and the angle formed between the first direction D1 and the fifth direction D5 may be, for example, any degree between 90 degrees and 180 degrees. The angle formed between the fourth direction D4 and the fifth direction D5 may be 90 degrees; however, example embodiments are not limited thereto, and the angle formed between the fourth direction D4 and the fifth direction D5 may be greater than or less than 90 degrees.

The block isolation structure 230 may include a first side surface 230_S1, which is connected to a side surface 211_S of the first word line isolation structure 211, and a second side surface 230_S2, which is connected to a side surface 212_S of the second word line isolation structure 212. The first and second side surfaces 230_S1 and 230_S2 of the block isolation structure 230 may be connected to each other. The first and second side surfaces 230_S1 and 230_S2 of the block isolation structure 230 may connect the side surface 211_S of the first word line isolation structure 211 to the side surface 212_S of the second word line isolation structure 212. The first side surface 230_S1 of the block isolation structure 230 may extend in the fifth direction D5, and the second side surface 230_S2 of the block isolation structure 230 may be extended in the fourth direction D4.

The block isolation structure 230 may further include a third side surface 230_S3, which is opposite to the first side surface 230_S1 of the block isolation structure 230, and a fourth side surface 230_S4, which is opposite to the second side surface 230_S2 of the block isolation structure 230. Each of the third and fourth side surfaces 230_S3 and 230_S4 of the block isolation structure 230 may be connected to a corresponding one of side surfaces 213_S of the third word line isolation structure 213.

The isolation portion 231 of the block isolation structure 230 may include two side surfaces, which are parallel to each other. As an example, the isolation portion 231 of the block isolation structure 230 may include the block isolation structure 230 and the first and third side surfaces 230_S1 and 230_S3.

The first block channel structures BCS1 may include first intervening channel structures ICS1, which are disposed between two connected ones of the isolation portions 231 of the block isolation structure 230. As an example, the first intervening channel structures ICS1 may be provided between a pair of the isolation portions 231, which are disposed between the first and second word line isolation structures 211 and 212 and are connected to each other. The first intervening channel structures ICS1 may be provided between the first and second side surfaces 230_S1 and 230_S2 of the block isolation structure 230.

The first intervening channel structures ICS1 may be overlapped with or by the isolation portions 231 of the block isolation structure 230 in the second direction D2. The first intervening channel structures ICS1 may be overlapped with or by the first and second side surfaces 230_S1 and 230_S2 of the block isolation structure 230 in the second direction D2.

Similar to the first block channel structures BCS1, the second block channel structures BCS2 may include second intervening channel structures ICS2, which are disposed between two connected ones of the isolation portions 231 of the block isolation structure 230. The second intervening channel structures ICS2 may be overlapped with or by the isolation portions 231 of the block isolation structure 230 in the second direction D2.

An angle between the word line isolation structure 210 and the isolation portion 231, which are connected to each other, may be greater than an angle between the isolation portions 231, which are connected to each other. As an example, an angle a1 between the side surface 211_S of the first word line isolation structure 211 and the first side surface 230_S1 of the block isolation structure 230 may be greater than an angle a2 between the first and second side surfaces 230_S1 and 230_S2 of the block isolation structure 230. As an example, an angle a3 between the side surface 212_S of the second word line isolation structure 212 and the second side surface 230_S2 of the block isolation structure 230 may be greater than the angle a2 between the first and second side surfaces 230_S1 and 230_S2 of the block isolation structure 230. For example, the angle a1 between the side surface 211_S of the first word line isolation structure 211 and the first side surface 230_S1 of the block isolation structure 230 may be greater than 90°.

Referring to FIG. 2E, the bit lines BL may include first overlap bit lines OBL1, second overlap bit lines OBL2, and share bit lines SBL.

The first overlap bit line OBL1 may overlap with or partially overlap some of the first block channel structures BCS1 and the block isolation structure 230. The first overlap bit line OBL1 may overlap or partially overlap with the first intervening channel structures ICS1 of the first block channel structures BCS1. The first overlap bit line OBL1 may be electrically connected to the first intervening channel structures ICS1 of the first block channel structures BCS1. The first overlap bit line OBL1 may overlap or partially overlap with the isolation portions 231 of the block isolation structure 230. The first overlap bit line OBL1 may overlap or partially overlap with the first and second side surfaces 230_S1 and 230_S2 of the block isolation structure 230.

The second overlap bit line OBL2 may overlap or partially overlap with some of the second block channel structures BCS2 and the block isolation structure 230. The second overlap bit line OBL2 may overlap or partially overlap with the second intervening channel structures ICS2 of the second block channel structures BCS2. The second overlap bit line OBL2 may be electrically connected to the second intervening channel structures ICS2 of the second block channel structures BCS2. The second overlap bit line OBL2 may overlap or partially overlap the isolation portions 231 of the block isolation structure 230. The second overlap bit line OBL2 may overlap or partially overlap the third and fourth side surfaces 230_S3 and 230_S4 of the block isolation structure 230.

The share bit line SBL may be disposed between the first overlap bit line OBL1 and the second overlap bit line OBL2. The share bit line SBL may overlap with some of the first block channel structures BCS1, some of the second block channel structures BCS2, and the block isolation structure 230. The share bit line SBL may overlap with some of the first intervening channel structures ICS1 of the first block channel structures BCS1. The share bit line SBL may overlap with some of the second intervening channel structures ICS2 of the second block channel structures BCS2.

One of the first intervening channel structures ICS1, which is overlapped or partially overlapped by the share bit line SBL, may be defined as a first sharing channel structure SCS1. One of the second intervening channel structures ICS2, which is overlapped by or partially overlapped by the share bit line SBL, may be defined as a second sharing channel structure SCS2. The share bit line SBL may be electrically connected to the first sharing channel structure SCS1 and the second sharing channel structure SCS2. The share bit line SBL may overlap or partially overlap the isolation portions 231 of the block isolation structure 230. The share bit line SBL may overlap or partially overlap with the first to fourth side surfaces 230_S1, 230_S2, 230_S3, and 230_S3 of the block isolation structure 230.

The first sharing channel structures SCS1 may be or may correspond to the first block channel structures BCS1 that are adjacent to the word line isolation structure 210 included in the second memory block BLK2. The second sharing channel structures SCS2 may be or may correspond to the second block channel structures BCS2 that are adjacent to the word line isolation structure 210 included in the first memory block BLK1.

For a semiconductor device according to some example embodiments, since the block isolation structure 230 is connected to the word line isolation structure 210 included in the first memory block BLK1 and the word line isolation structure 210 included in the second memory block BLK2, a space between the first memory block BLK1 and the second memory block BLK2 may be reduced or minimized.

For a semiconductor device according to some example embodiments, owing to the shape of the block isolation structure 230, the first block channel structures BCS1 may include the first intervening channel structures ICS1 and first sharing channel structures SCS1, and the second block channel structures BCS2 may include the second intervening channel structures ICS2 and second sharing channel structures SCS2. Accordingly, an integration density of the semiconductor device may be increased.

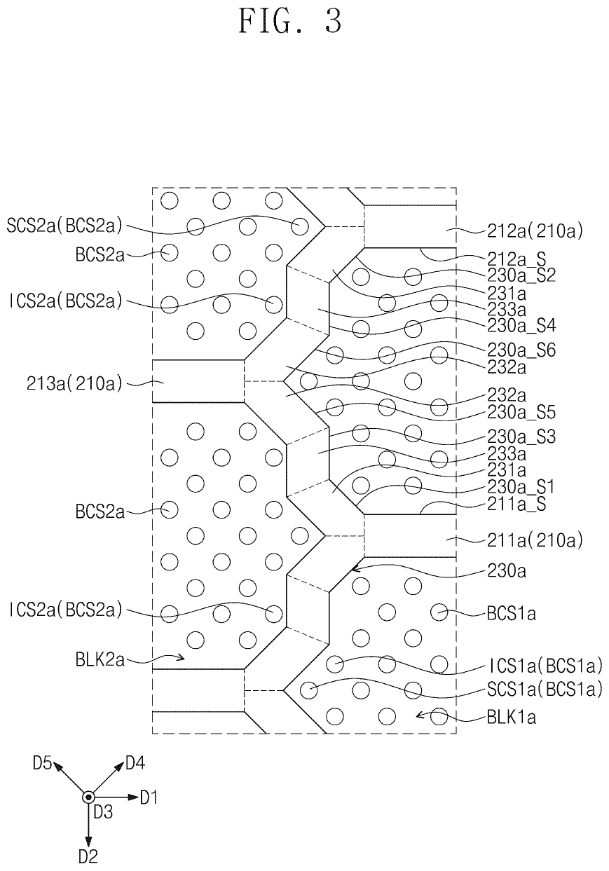

FIG. 3 is a plan view illustrating a semiconductor device according to some example embodiments.

Referring to FIG. 3, a semiconductor device may include first block channel structures BCS1a, which are included in a first memory block BLK1a, and second block channel structures BCS2a, which are included in a second memory block BLK2a. The isolation structure of the semiconductor device may include a block isolation structure 230a, which is provided to separate the first block channel structures BCS1a from the second block channel structures BCS2a, and a word line isolation structure 210a, which is provided between the first block channel structures BCS1a or between the second block channel structures BCS2a.

The word line isolation structures 210a may include a first word line isolation structure 211a and a second word line isolation structure 212a, which are included in the first memory block BLK1a, and a third word line isolation structure 213a, which is included in the second memory block BLK2a.

The block isolation structure 230a may include first isolation portions 231a, second isolation portions 232a, and third isolation portions 233a. The first isolation portion 231a may be a portion that is connected to the word line isolation structure 210a included in the first memory block BLK1a. As an example, the first isolation portion 231a may be connected to the first word line isolation structure 211a. The second isolation portion 232a may be a portion that is connected to the word line isolation structure 210a included in the second memory block BLK2a. As an example, the second isolation portion 232a may be connected to the third word line isolation structure 213a. The third isolation portion 233a may be a portion connecting the first isolation portion 231a to the second isolation portion 232a.

Two word line isolation structures 210a may be connected to each other by the first to third isolation portions 231a, 232a, and 233a. As an example, the first word line isolation structure 211a and the third word line isolation structure 213a may be connected to each other by the first to third isolation portions 231a, 232a, and 233a. Two first isolation portions 231a may be connected to each other. Two second isolation portions 232a may be connected to each other. Two first isolation portions 231a or two second isolation portions 232a may be connected to one word line isolation structure 210a.

Each of the first and second isolation portions 231a and 232a may extend in the fourth or fifth direction D4 or D5. The third isolation portion 233a may extend in the second direction D2.

The block isolation structure 230a may include a first side surface 230a_S1 connected to a side surface 211a_S of the first word line isolation structure 211a, a second side surface 230a_S2 connected to a side surface 212a_S of the second word line isolation structure 212a, a third side surface 230a_S3 connected to the first side surface 230a_S1 of the block isolation structure 230a, a fourth side surface 230a_S4 connected to the second side surface 230a_S2 of the block isolation structure 230a, a fifth side surface 230a_S5 connected to the third side surface 230a_S3 of the block isolation structure 230a, and a sixth side surface 230a S6 connected to the fourth side surface 230a_S4 of the block isolation structure 230a. The fifth and sixth side surfaces 230a_S5 and 230a_S6 of the block isolation structure 230a may be connected to each other. The first to sixth side surfaces 230a_S1, 230a_S2, 230a_S3, 230a_S4, 230a_S5, and 230a_S6 of the block isolation structure 230a may connect the side surface 211a_S of the first word line isolation structure 211a to the side surface 212a_S of the second word line isolation structure 212a.

Each of the first and second side surfaces 230a_S1 and 230a_S2 of the block isolation structure 230a may be a side surface of the first isolation portion 231a. Each of the third and fourth side surfaces 230a_S3 and 230a_S4 of the block isolation structure 230a may be a side surface of the third isolation portion 233a. Each of the fifth and sixth side surfaces 230a_S5 and 230a_S6 of the block isolation structure 230a may be a side surface of the second isolation portion 232a.

The first and fifth side surfaces 230a_S1 and 230a_S5 of the block isolation structure 230a may extend in the fifth direction D5. The second and sixth side surfaces 230a_S2 and 230a_S6 of the block isolation structure 230a may extend in the fourth direction D4. The third and fourth side surfaces 230a_S3 and 230a_S4 of the block isolation structure 230a may be extended in the second direction D2.

The first block channel structures BCS1a may include first intervening channel structures ICS1a, which are disposed between the first to third isolation portions 231a, 232a, and 233a of the block isolation structure 230a. The first intervening channel structures ICS1a may be disposed between the first and second side surfaces 230a_S1 and 230a_S2 of the block isolation structure 230a or between the fifth and sixth side surfaces 230a_S5 and 230a_S6 of the block isolation structure 230a.

The first intervening channel structures ICS1a may be overlapped with or by at least one of the first isolation portion 231a, the second isolation portion 232a, and the third isolation portion 233a of the block isolation structure 230a in the second direction D2. The first intervening channel structures ICS1a may be overlapped with or by at least one of the first to sixth side surfaces 230a_S1, 230a_S2, 230a_S3, 230a_S4, 230a_S5, and 230a_S6 of the block isolation structure 230a in the second direction D2.

Similar to the first block channel structures BCS1a, the second block channel structures BCS2a may include second intervening channel structures ICS2a, which are disposed between the first to third isolation portions 231a, 232a, and 233a of the block isolation structure 230a.

An angle between the word line isolation structure 210a and the first isolation portion 231a, which are connected to each other, may be greater than an angle between the first isolation portions 231a, which are connected to each other. An angle between the word line isolation structure 210a and the second isolation portion 232a, which are connected to each other, may be greater than an angle between the second isolation portions 232a, which are connected to each other.

An angle between the side surface 211a_S of the first word line isolation structure 211a and the first side surface 230a_S1 of the block isolation structure 230a may be greater than an angle between the fifth and sixth side surfaces 230a_S5 and 230a_S6 of the block isolation structure 230.

The bit lines of the semiconductor device may include a first overlap bit line, which overlaps or at least partially overlaps with the first intervening channel structures ICS1a and the block isolation structure 230a, a second overlap bit line, which overlaps or at least partially overlaps with the second intervening channel structures ICS2a and the block isolation structure 230a, and a share bit line, which is provided between the first overlap bit line and the second overlap bit line. The first block channel structures BCS1a may include first sharing channel structures SCS1a, which are overlapped or at least partially overlapped by the share bit line. The second block channel structures BCS2a may include second sharing channel structures SCS2a, which are overlapped with the share bit line.

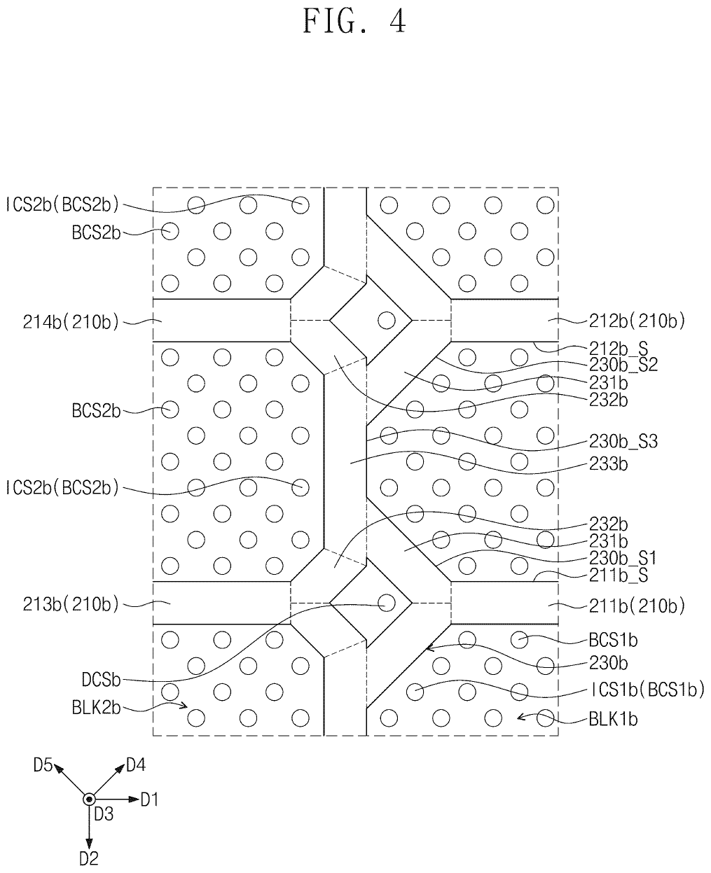

FIG. 4 is a plan view illustrating a semiconductor device according to some example embodiments.

Referring to FIG. 4, a semiconductor device may include first block channel structures BCS1b, which are included in a first memory block BLK1b, and second block channel structures BCS2b, which are included in a second memory block BLK2b. The isolation structure of the semiconductor device may include a block isolation structure 230b, which is provided to separate the first block channel structures BCS1b from the second block channel structures BCS2b, and a word line isolation structure 210b, which is disposed between the first block channel structures BCS1b or between the second block channel structures BCS2b.

The word line isolation structures 210b may include a first word line isolation structure 211b and a second word line isolation structure 212b, which are included in the first memory block BLK1b, and a third word line isolation structure 213b and a fourth word line isolation structure 214b, which are included in the second memory block BLK2b.

The block isolation structure 230b may include first isolation portions 231b, second isolation portions 232b, and third isolation portions 233b. The first isolation portion 231b may be a portion that is connected to the word line isolation structure 210b included in the first memory block BLK1b. As an example, the first isolation portion 231b may be connected to the first word line isolation structure 211b. The second isolation portion 232b may be a portion that is connected to the word line isolation structure 210b included in the second memory block BLK2b. As an example, the second isolation portion 232b may be connected to the third word line isolation structure 213b. The third isolation portion 233b may be a portion connecting the first isolation portion 231b to the second isolation portion 232b. Two first isolation portions 231b or two second isolation portions 232b may be connected to one word line isolation structure 210b.

Each of the first and second isolation portions 231b and 232b may extend in the fourth or fifth direction D4 or D5. The third isolation portion 233b may be extended in the second direction D2. A length of the first isolation portion 231b may be larger than a length of the second isolation portion 232b. As an example, a length, in the fourth direction D4, of the first isolation portion 231b extending in the fourth direction D4 may be greater than a length, in the fourth direction D4, of the second isolation portion 232b extending in the fourth direction D4.

An angle between the first the isolation portion 231b and the word line isolation structure 210b connected thereto may be equal to an angle between the second isolation portion 232b and the word line isolation structure 210b connected thereto.

The block isolation structure 230b may include a first side surface 230b_S1, which is connected to a side surface 211b_S of the first word line isolation structure 211b, a second side surface 230b_S2, which is connected to a side surface 212b_S of the second word line isolation structure 212b, and a third side surface 230b_S3, which is connected to the first and second side surfaces 230b_S1 and 230b_S2 of the block isolation structure 230b. The first to third side surfaces 230b_S1, 230b_S2, and 230b_S3 of the block isolation structure 230b may connect the side surface 211b_S of the first word line isolation structure 211b to the side surface 212b_S of the second word line isolation structure 212b.

The first side surface 230b_S1 of the block isolation structure 230b may extend in the fifth direction D5. The second side surface 230b_S2 of the block isolation structure 230b may extend in the fourth direction D4. The third side surface 230b_S3 of the block isolation structure 230b may extend in the second direction D2.

The first block channel structures BCS1b may include first intervening channel structures ICS1b, which are disposed between the first isolation portions 231b of the block isolation structure 230b. The first intervening channel structures ICS1b may be disposed between the first and second side surfaces 230b_S1 and 230b_S2 of the block isolation structure 230b.

The first intervening channel structures ICS1b may be overlapped with the first isolation portion 231b of the block isolation structure 230b in the second direction D2. The first intervening channel structures ICS1b may be overlapped with or by at least one of the first and second side surfaces 230b_S1 and 230b_S2 of the block isolation structure 230b in the second direction D2.

Similar to the first block channel structures BCS1b, the second block channel structures BCS2b may include second intervening channel structures ICS2b, which are disposed between the second isolation portions 232b of the block isolation structure 230b.

The bit lines of the semiconductor device may include a first overlap bit line, which overlaps or at least partially overlaps with the first intervening channel structures ICS1b and the first isolation portions 231b of the block isolation structure 230b, and a second overlap bit line, which overlaps or at least partially overlaps with the second intervening channel structures ICS2b and the second isolation portions 232b of the block isolation structure 230b.

The semiconductor device may further include a dummy channel structure DCSb, which is enclosed by the block isolation structure 230b. The dummy channel structure DCSb may be provided to penetrate the gate stack. The dummy channel structure DCSb may be enclosed by the first to third isolation portions 231b, 232b, and 233b of the block isolation structure 230b. The dummy channel structures DCSb may not be electrically connected to other components of the semiconductor device.

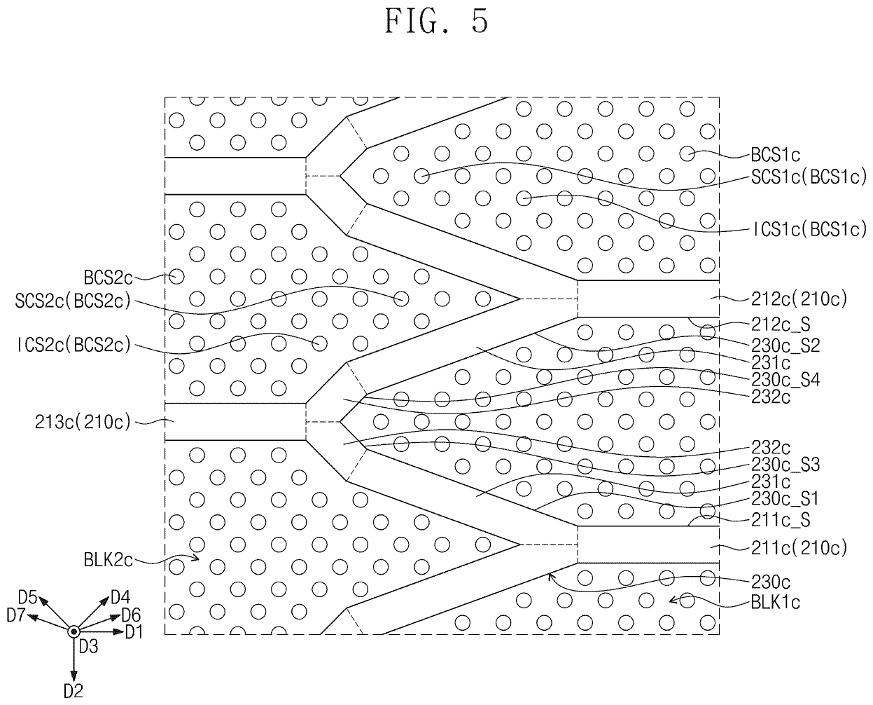

FIG. 5 is a plan view illustrating a semiconductor device according to some example embodiments.

Referring to FIG. 5, a semiconductor device may include first block channel structures BCS1c, which are included in a first memory block BLK1c, and second block channel structures BCS2c, which are included in a second memory block BLK2c. The isolation structure of the semiconductor device may include a block isolation structure 230c, which is provided to separate the first block channel structures BCS1c from the second block channel structures BCS2c, and a word line isolation structure 210c, which is provided between the first block channel structures BCS1c or between the second block channel structures BCS2c.

The word line isolation structures 210c may include a first word line isolation structure 211c and a second word line isolation structure 212c, which are included in the first memory block BLK1c, and a third word line isolation structure 213c, which is included in the second memory block BLK2c.

The block isolation structure 230c may include first isolation portions 231c and second isolation portions 232c. The first isolation portion 231c may be a portion that is connected to the word line isolation structure 210c included in the first memory block BLK1c. As an example, the first isolation portion 231c may be connected to the first word line isolation structure 211c. The second isolation portion 232c may be a portion that is connected to the word line isolation structure 210c included in the second memory block BLK2c. As an example, the second isolation portion 232c may be connected to the third word line isolation structure 213c. Two first isolation portions 231c or two second isolation portions 232c may be connected to one word line isolation structure 210c.

Each of the first the isolation portions 231c may extend in a sixth or seventh direction D6 or D7. The sixth direction D6 may not be parallel to the first to fifth directions D1, D2, D3, D4, and D5. As an example, the sixth direction D6 may be a horizontal direction that is orthogonal to the third direction D3. The seventh direction D7 may not be parallel to the first to sixth directions D1, D2, D3, D4, D5, and D6. As an example, the seventh direction D7 may be a horizontal direction that is orthogonal to the third direction D3. Each of the second isolation portions 232c may be extended in the fourth or fifth direction D4 or D5. A length of the first isolation portion 231c may be larger than a length of the second isolation portion 232c. As an example, a length, in the sixth direction D6, of the first isolation portion 231c extending in the sixth direction D6 may be larger than a length, in the fourth direction D4, of the second isolation portion 232c extending in the fourth direction D4.

An angle between the first isolation portion 231c and the word line isolation structure 210c connected thereto may be greater than an angle between the second isolation portion 232c and the word line isolation structure 210c connected thereto.

The block isolation structure 230c may include a first side surface 230c_S1, which is connected to a side surface 211c_S of the first word line isolation structure 211c, a second side surface 230c_S2, which is connected to a side surface 212c_S of the second word line isolation structure 212c, a third side surface 230c_S3, which is connected to the first side surface 230c_S1 of the block isolation structure 230c, and a fourth side surface 230c_S4, which is connected to the second side surface 230c_S2 of the block isolation structure 230c. The third and fourth side surfaces 230c_S3 and 230c_S4 of the block isolation structure 230c may be connected to each other. The first to fourth side surfaces 230c_S1, 230c_S2, 230c_S3, and 230c_S4 of the block isolation structure 230c may connect the side surface 211c_S of the first word line isolation structure 211c to the side surface 212c_S of the second word line isolation structure 212c.

The first side surface 230c_S1 of the block isolation structure 230c may be extended in the seventh direction D7. The second side surface 230c_S2 of the block isolation structure 230c may be extended in the sixth direction D6. The third side surface 230c_S3 of the block isolation structure 230c may be extended in the fifth direction D5. The fourth side surface 230c_S4 of the block isolation structure 230c may be extended in the fourth direction D4.

The first block channel structures BCS1c may include first intervening channel structures ICS1c, which are disposed between the first and second isolation portions 231c and 232c of the block isolation structure 230c. The first intervening channel structures ICS1c may be disposed between the first to fourth side surfaces 230c_S1, 230c_S2, 230c_S3, and 230c_S4 of the block isolation structure 230c.

The first intervening channel structures ICS1c may be overlapped with or by at least one of the first and second isolation portions 231b and 232b of the block isolation structure 230c in the second direction D2. The first intervening channel structures ICS1c may be overlapped with at least one of the first to fourth side surfaces 230c_S1, 230c_S2, 230c_S3, and 230c_S4 of the block isolation structure 230c in the second direction D2.

Similar to the first block channel structures BCS1c, the second block channel structures BCS2c may include second intervening channel structures ICS2c, which are disposed between the first and second isolation portions 231c and 232c of the block isolation structure 230c.

The bit lines of the semiconductor device may include a first overlap bit line, which overlaps or at least partially overlaps with the first intervening channel structures ICS1c and the block isolation structure 230c, a second overlap bit line, which overlaps or at least partially overlaps with the second intervening channel structures ICS2c and the block isolation structure 230c, and a share bit line, which is disposed between the first overlap bit line and the second overlap bit line. The first block channel structures BCS1c may include first sharing channel structures SCS1c, which are overlapped with the share bit line. The second block channel structures BCS2c may include second sharing channel structures SCS2c, which are overlapped with the share bit line.

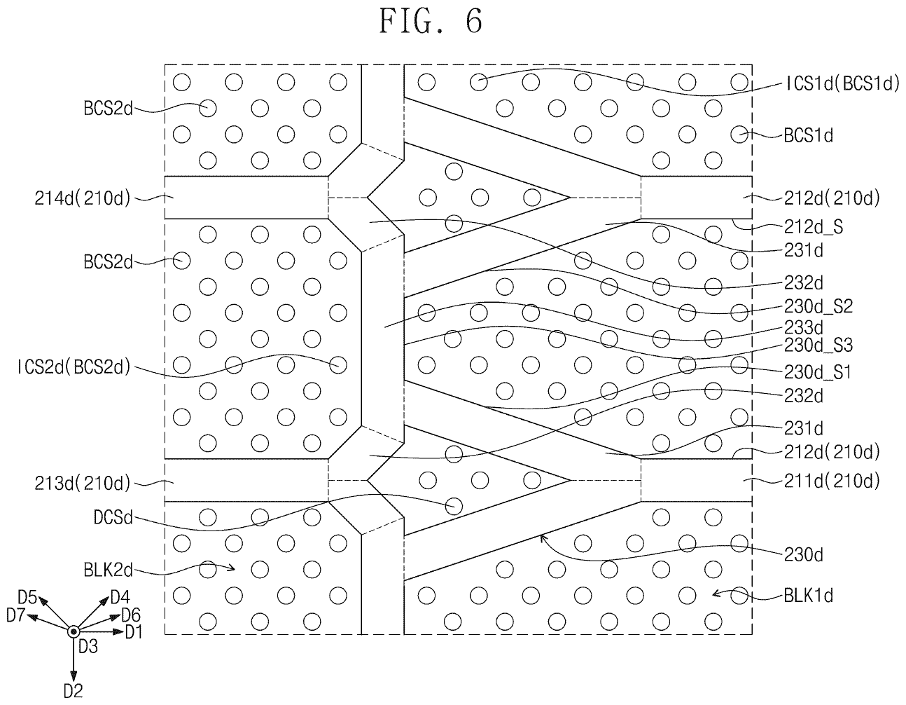

FIG. 6 is a plan view illustrating a semiconductor device according to some example embodiments.

Referring to FIG. 6, a semiconductor device may include first block channel structures BCS1d, which are included in a first memory block BLK1d, and second block channel structures BCS2d, which are included in a second memory block BLK2d. The isolation structure of the semiconductor device may include a block isolation structure 230d, which is provided to separate the first block channel structures BCS1d from the second block channel structures BCS2d, and a word line isolation structure 210d, which is provided between the first block channel structures BCS1d or between the second block channel structures BCS2d.

The word line isolation structures 210d may include a first word line isolation structure 211d and a second word line isolation structure 212d, which are included in the first memory block BLK1d, and a third word line isolation structure 213d and a fourth word line isolation structure 214d, which are included in the second memory block BLK2d.

The block isolation structure 230d may include first isolation portions 231d, second isolation portions 232d, and third isolation portions 233d. The first isolation portion 231d may be a portion that is connected to the word line isolation structure 210d included in the first memory block BLK1d. As an example, the first isolation portion 231d may be connected to the first word line isolation structure 211d. The second isolation portion 232d may be a portion that is connected to the word line isolation structure 210d included in the second memory block BLK2d. As an example, the second isolation portion 232d may be connected to the third word line isolation structure 213d. The third isolation portion 233d may be a portion connecting the first isolation portion 231d to the second isolation portion 232d. Two first isolation portions 231d or two second isolation portions 232d may be connected to one word line isolation structure 210d.

The first isolation portion 231d may extend in the sixth or seventh direction D6 or D7. The second isolation portion 232d may extend in the fourth or fifth direction D4 or D5. The third isolation portion 233d may extend in the second direction D2. A length of the first isolation portion 231d may be larger than a length of the second isolation portion 232d. As an example, a length, in the sixth direction D6, of the first isolation portion 231d extending in the sixth direction D6 may be larger or greater than a length, in the fourth direction D4, of the second isolation portion 232d extending in the fourth direction D4.

An angle between the first isolation portion 231d and the word line isolation structure 210d connected thereto may be greater than an angle between the second isolation portion 232d and the word line isolation structure 210d connected thereto.

The block isolation structure 230d may include a first side surface 230d_S1, which is connected to a side surface 211d_S of the first word line isolation structure 211d, a second side surface 230d_S2, which is connected to a side surface 212d_S of the second word line isolation structure 212d, and a third side surface 230d_S3, which is connected to the first and second side surfaces 230d_S1 and 230d_S2 of the block isolation structure 230d. The first to third side surfaces 230d_S1, 230d_S2, and 230d_S3 of the block isolation structure 230d may connect the side surface 211d_S of the first word line isolation structure 211d to the side surface 212d_S of the second word line isolation structure 212d.

The first side surface 230d_S1 of the block isolation structure 230d may extend in the seventh direction D7. The second side surface 230d_S2 of the block isolation structure 230d may extend in the sixth direction D6. The third side surface 230d_S3 of the block isolation structure 230d may extend in the second direction D2.

The first block channel structures BCS1d may include first intervening channel structures ICS1d, which are disposed between the first isolation portions 231d of the block isolation structure 230d. The first intervening channel structures ICS1d may be disposed between the first and second side surfaces 230d_S1 and 230d_S2 of the block isolation structure 230d.

The first intervening channel structures ICS1d may be overlapped with or by the first isolation portion 231d of the block isolation structure 230d in the second direction D2. The first intervening channel structures ICS1d may be overlapped with or by at least one of the first and second side surfaces 230d_S1 and 230d_S2 of the block isolation structure 230d in the second direction D2.

Similar to the first block channel structures BCS1d, the second block channel structures BCS2d may include second intervening channel structures ICS2d, which are disposed between the second isolation portions 232d of the block isolation structure 230d.

The bit lines of the semiconductor device may include a first overlap bit line, which overlaps or partially overlaps with the first intervening channel structures ICS1d and the first isolation portions 231d of the block isolation structure 230d, and a second overlap bit line, which overlaps or partially overlaps with the second intervening channel structures ICS2d and the second isolation portions 232d of the block isolation structure 230d.

The semiconductor device may further include a dummy channel structure DCSd, which is enclosed by the block isolation structure 230d. The dummy channel structure DCSd may be provided to penetrate the gate stack. The dummy channel structure DCSd may be enclosed by the first to third isolation portions 231d, 232d, and 233d of the block isolation structure 230d.

In a semiconductor device according to some example embodiments and an electronic system including the same, it may be possible to reduce a space between adjacent ones of memory blocks.

While some example embodiments of inventive concepts have been particularly shown and described, it will be understood by one of ordinary skill in the art that variations in form and detail may be made therein without departing from the spirit and scope of the attached claims. Additional example embodiments are not necessarily mutually exclusive. For example, some example embodiments may include one or more features described with reference to one or more drawings, and may also include one or more other features described with reference to one or more other drawings.

What is claimed is:

1. A semiconductor device, comprising:
a gate stack including insulating patterns and conductive patterns, which are alternately stacked;
first block channel structures penetrating the gate stack;
second block channel structures penetrating the gate stack; and
an isolation structure penetrating the gate stack, wherein
the isolation structure comprises a block isolation structure between the first block channel structures and the second block channel structures, a first word line isolation structure between the first block channel structures, and a second word line isolation structure between the first block channel structures and adjacent to the first word line isolation structure,
the block isolation structure comprises a first side surface connected to a side surface of the first word line isolation structure, and a second side surface connected to a side surface of the second word line isolation structure, and
the first block channel structures comprise an intervening channel structure between the first and second side surfaces of the block isolation structure.

2. The semiconductor device of claim 1, wherein the first and second side surfaces of the block isolation structure are connected to each other.

3. The semiconductor device of claim 2, wherein a first angle between the first and second side surfaces of the block isolation structure is less than a second angle between the first side surface of the block isolation structure and the side surface of the first word line isolation structure.

4. The semiconductor device of claim 1, wherein
the block isolation structure comprises a third side surface opposite to the first side surface of the block isolation structure, and a fourth side surface opposite to the second side surface of the block isolation structure, and
the isolation structure further comprises a third word line isolation structure connected to the third and fourth side surfaces of the block isolation structure and arranged between the second block channel structures.

5. The semiconductor device of claim 1, further comprising:
a share bit line overlapping the block isolation structure, wherein
the first block channel structures comprise a first sharing channel structure electrically connected to the share bit line, and
the second block channel structures comprise a second sharing channel structure electrically connected to the share bit line.

6. The semiconductor device of claim 1, further comprising:
bit lines which extending in a first direction,
wherein the intervening channel structure is at least partially overlapped with the first and second side surfaces of the block isolation structure in the first direction.

7. The semiconductor device of claim 6, wherein,
the side surface of the first word line isolation structure and the side surface of the second word line isolation structure extend in a second direction crossing the first direction,
the first side surface of the block isolation structure extends in a third direction crossing the first direction and the second direction, and
the second side surface of the block isolation structure extends in a fourth direction crossing the first direction, the second direction, and the third direction.

8. The semiconductor device of claim 1, further comprising:
a dummy channel structure penetrating the gate stack, wherein,
the dummy channel structure is enclosed by the block isolation structure.

9. The semiconductor device of claim 1, further comprising:
an overlap bit line, which at least partially overlaps the first and second side surfaces of the block isolation structure,
wherein the intervening channel structure is at least partially overlapped by the overlap bit line.

10. The semiconductor device of claim 1, wherein
the isolation structure further comprises a third word line isolation structure connected to the block isolation structure and arranged between the second block channel structures,
the block isolation structure comprises a first isolation portion connected to the first word line isolation structure, and a second isolation portion connected to the third word line isolation structure, and
a first length of the first isolation portion of the block isolation structure is greater than a second length of the second isolation portion of the block isolation structure.

11. The semiconductor device of claim 10, wherein the block isolation structure further comprises a third isolation portion connected to the first and second isolation portions of the block isolation structure.

12. The semiconductor device of claim 10, wherein a first angle between the first word line isolation structure and the first isolation portion of the block isolation structure is equal to a second angle between the third word line isolation structure and the second isolation portion of the block isolation structure.

13. The semiconductor device of claim 10, wherein a first angle between the first word line isolation structure and the first isolation portion of the block isolation structure is greater than a second angle between the third word line isolation structure and the second isolation portion of the block isolation structure.

14. The semiconductor device of claim 10, wherein
the first isolation portion of the block isolation structure comprises two side surfaces that are parallel to each other, and
the second isolation portion of the block isolation structure comprises two side surfaces that are parallel to each other.

15. A semiconductor device, comprising:
a gate stack including insulating patterns and conductive patterns, which are alternately stacked;
bit lines on the gate stack;
first block channel structures penetrating the gate stack;
second block channel structures penetrating the gate stack; and
an isolation structure penetrating the gate stack,
wherein the isolation structure comprises a block isolation structure between the first block channel structures and the second block channel structures, a first word line isolation structure between the first block channel structures, and a second word line isolation structure between the first block channel structures and adjacent to the first word line isolation structure,
the block isolation structure comprises a first side surface connected to a side surface of the first word line isolation structure, and a second side surface connected to a side surface of the second word line isolation structure,
the bit lines comprise a first overlap bit line at least partially overlapping the first and second side surfaces of the block isolation structure, and
the first block channel structures comprise a first intervening channel structure at least partially overlapped by the first overlap bit line.

16. The semiconductor device of claim 15, wherein
the isolation structure further comprises a third word line isolation structure between the second block channel structures,
the block isolation structure comprises a third side surface and a fourth side surface respectively connected to side surfaces of the third word line isolation structure,
the bit lines comprise a second overlap bit line, which at least partially overlapping the third and fourth side surfaces of the block isolation structure, and
the second block channel structures comprise a second intervening channel structure, at least partially overlapped by the second overlap bit line.

17. The semiconductor device of claim 16, wherein
the bit lines further comprise a share bit line between the first overlap bit line and the second overlap bit line,
the first block channel structures comprise a first sharing channel structure electrically connected to the share bit line, and
the second block channel structures comprise a second sharing channel structure electrically connected to the share bit line.

18. The semiconductor device of claim 17, wherein an angle between the first side surface of the block isolation structure and the side surface of the first word line isolation structure is greater than 90°.

19. An electronic system, comprising:
a main substrate;
a semiconductor device on the main substrate; and
a controller on the main substrate and electrically connected to the semiconductor device,
wherein the semiconductor device comprises,
a gate stack including insulating patterns and conductive patterns, which are alternately stacked,
bit lines on the gate stack,
first block channel structures penetrating the gate stack,
second block channel structures penetrating the gate stack, and
an isolation structure penetrating the gate stack,
wherein the isolation structure comprises a block isolation structure between the first block channel structures and the second block channel structures, a first word line isolation structure between the first block channel structures, and a second word line isolation structure between the first block channel structures and adjacent to the first word line isolation structure,
the bit lines comprise a first overlap bit line at least partially overlapping the block isolation structure, a second overlap bit line at least partially overlapping the block isolation structure, and a share bit line arranged between the first overlap bit line and the second overlap bit line,
the first block channel structures comprise a first intervening channel structure electrically connected to the first overlap bit line, and a first sharing channel structure electrically connected to the share bit line, and
the second block channel structures comprise a second intervening channel structure electrically connected to the second overlap bit line, and a second sharing channel structure electrically connected to the share bit line.

20. The electronic system of claim 19, wherein
the block isolation structure comprises a plurality of isolation portions, and
each of the first and second intervening channel structures and the first and second sharing channel structures is between the plurality of isolation portions of the block isolation structure.
